(19) United States
(12) Patent Application Publication
(10) Pub. No.: US 2006/0236185 A1
(43) Pub. Date: Oct. 19, 2006

(54) Multiple function results using single pattern and method

(76) Inventor: Ronald Baker, Raleigh, NC (US)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/098,318

(22) Filed: Apr. 4, 2005

(51) Int. Cl. G06F 11/00; G01R 31/28

(52) U.S. Cl. 714/738

(57) ABSTRACT

A testing system for testing a manufactured semiconductor component includes a main processor and a pattern generator. The main processor is configured to run a main program. The pattern generator is configured to generate a plurality of functional test patterns, and each test pattern is assembled to test the manufactured semiconductor component thereby producing a test result for each test pattern. The main processor and main program communicate with the pattern generator and functional test patterns such that the plurality of functional test patterns is sequentially run on the manufactured semiconductor component. Furthermore, the main program receives the test result of each functional test pattern after it is run. The manufactured semiconductor component continues to operate between each of the functional test patterns.

The present invention relates to a semiconductor testing apparatus, and particularly to a semiconductor testing apparatus for testing multiple function results from a single pattern. Many memory devices, including dynamic random access memories (DRAMs), are implemented as integrated circuits. While the size of such integrated circuits has decreased, the storage capacity operating speed and expanded capabilities of such memory device have increased functionality, but also have added challenges in testing.

Integrated circuits that implement memory devices must be reliable. Accordingly, memory devices are tested after they are manufactured. As the capacity and capabilities of memory device has increased, broad ranges of tests have been automated. Different memory device may prescribe different testing routines. DRAM components are typically subjected to many functional tests under different conditions. After each functional test is administered, the device is evaluated as either “pass” or as “fail” based on the result of these testes. In current testing systems, at the end of the function test pattern, the component input clock is stopped and the test system enables either the pass or fail indication. Then a new pattern for a new functional test is started requiring a restart of the input clock and other input signals.

For these and other reasons, there is a need for the present invention.

### SUMMARY

One embodiment of the present invention is a testing system for testing a manufactured semiconductor component. The testing system includes a main processor and a pattern generator. The main processor is configured to run a main program. The pattern generator is configured to generate a plurality of functional test patterns, and each test pattern is assembled to test the manufactured semiconductor component thereby producing a test result for each test pattern. The main processor and main program communicate with the pattern generator and functional test patterns such that the plurality of functional test patterns is sequentially run on the manufactured semiconductor component. Furthermore, the main program receives the test result of each functional test pattern after it is run. The manufactured semiconductor component continues to operate between each of the functional test patterns.

### BRIEF DESCRIPTION OF THE DRAWINGS

FIG. 1 illustrates a schematic block diagram of a test system.

FIG. 2 is flow diagram illustrating one embodiment of a test system according to one embodiment of the present invention.

FIG. 3 is a flow diagram illustrating an alternative embodiment of a test system according to one embodiment of the present invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

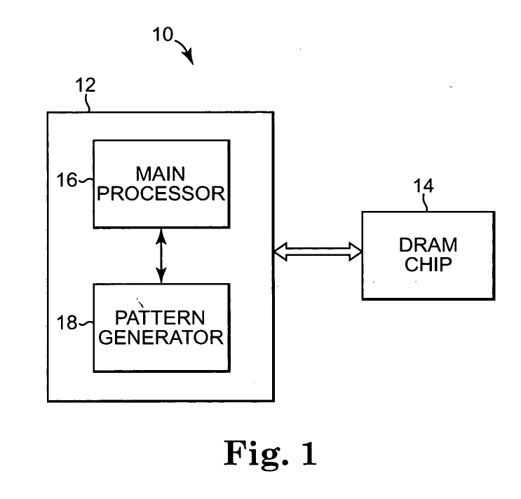

FIG. 1 illustrates test system 10 including semiconductor testing apparatus 12 and semiconductor chip 14. In one embodiment, semiconductor chip 14 is a dynamic random access memory (DRAM) chip. In one embodiment, testing apparatus 12 further includes main processor 16 and pattern generator 18. In operation, test system 10 provides flexible communication between main processor 16 and pattern generator 18 such that semiconductor chip 14 under test may be allowed to keep operating while there is communication between main processor 16 and pattern generator 18. Thus, in one embodiment, main processor 16 may retrieve results of tests from pattern generator 18, while pattern generator 18 continues to simultaneously operate semiconductor chip 14.

In one embodiment, semiconductor chip 14 is a memory chip, such as a DRAM chip. In one case, pattern generator 18 operates under the control of a main program running in main processor 16. Pattern generator 18 is then configured to produce a plurality of functional test patterns that are operated on the semiconductor chip 14 under test. The main program running in main processor 16 causes a sequence of functional test patterns to be run on semiconductor chip 14. After each functional test pattern is run on semiconductor chip 14, a test result is retrieved by main program running in main processor 16. Meanwhile, semiconductor chip 14 is kept active and running while these test results are retrieved such that when the next functional test pattern in the sequence in run, the semiconductor chip 14 never goes to a static or undefined state.

For example, pattern generator 18 may generate a first functional test pattern for a memory device that writes “zeroes” to all the address locations in the entire memory device, and then read zeroes from the entire device. If all zeroes are indeed read from the entire device, then the test result is a “pass.” If any return a “one” rather than a zero, however, then the test result is a “fail.” In either the case of a pass or of a fail, the main program that is running in main processor 16 retrieves the test result. The results may then be stored.

Then, pattern generator 18 may generate a second functional test pattern for a memory device that write “ones” to all the address locations in the entire memory device, and then read ones from the entire device. If all ones are indeed read from the entire device, then the test result is a “pass.” If any return a “zero” rather than a one, however, then the test result is a “fail.” In either the case of a pass or of a fail, the main program that is running in main processor 16 retrieves the test result. The results may then be stored.

This process may be repeated such that pattern generator 18 may generate any number of multiple functional test patterns. Unlike prior systems, however, test system 10 keeps semiconductor chip 14 active between each of the functional test patterns. Semiconductor chip 14 continues running, even after the completion of each functional test pattern, while the test results for the various functional test patterns are retrieved by the main program running in main processor 16. In this way, the semiconductor chip 14 never goes to a static or undefined state between the individual functional test patterns.

In one embodiment of test system 10, semiconductor chip 14 receives clock signals and related input signals that are used in the functional test patterns. In order to ensure that semiconductor chip 14 remains active between the running of functional test patterns, in one embodiment semiconductor chip 14 continues to receive these clock and related input signals even between the running of functional test patterns. This ensures that semiconductor chip 14 never goes to a static or undefined state between the individual functional test patterns.

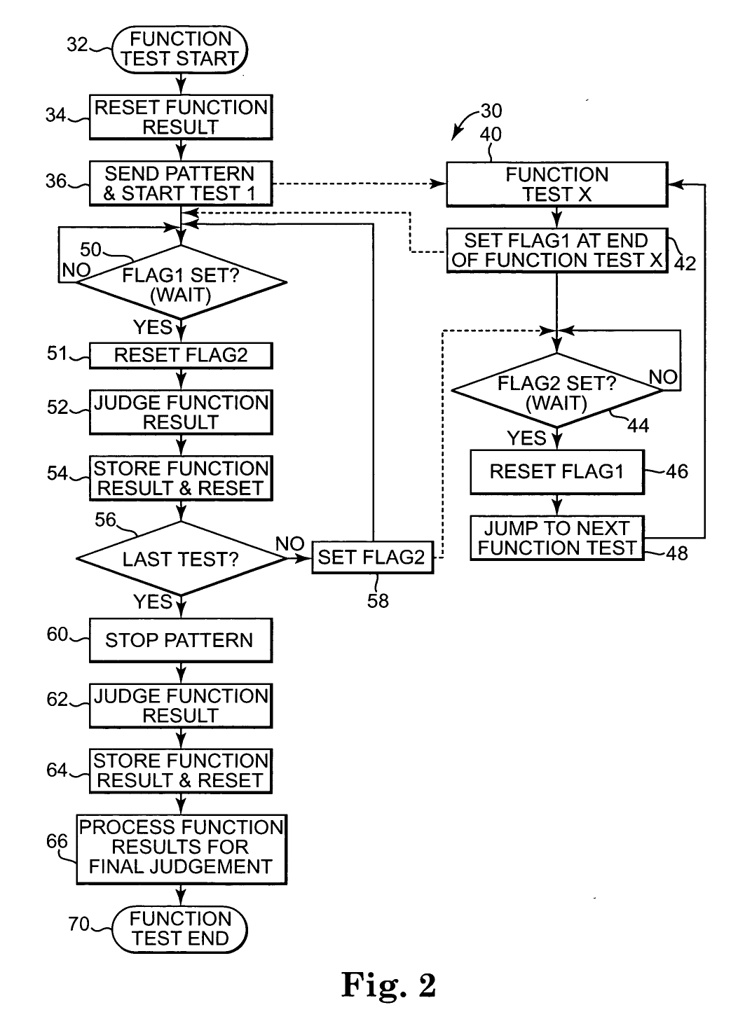

FIG. 2 is flow diagram illustrating one embodiment of test system 10 according to an embodiment of the present invention. In one embodiment, steps 32 through 36 and steps 50 through 70 represent functions of the main program that is running in the main processor 16, and in that same embodiment, steps 40 though 48 represent functional test patterns that are running in the pattern generator 18.

At step 32, functional test patterns start in the main program. At step 34, any test results of the functional test patterns are reset, thereby eliminating any pass/fail decision from previous patterns. Next at step 36, a functional test pattern is sent to the pattern generator 18. In this way, the pattern generator 18 at step 40 initiates a first functional test pattern. Thus, the pattern generator 18 powers up the semiconductor chip 14 under test, and it writes data to chip 14 and reads data from chip 14. Once the functional test pattern is finished, an internal flag (FLAG1) in the pattern generator 18 is set at step 42 at the end of this functional test pattern.

At the same time that the functional test pattern is initiated by the pattern generator 18 at step 40, the main program in the main processor 16 enters an infinite loop at step 50. When the functional test pattern is initiated by the pattern generator 18 at step 40, FLAG1 has not yet been set such that the main program in the main processor 16 continues to loop at step 50. This infinite loop continues until FLAG1 is set at the end of the functional test pattern at step 42. After the functional test pattern ends and returns a result at step 42, FLAG2 is reset at step 51 and then the result from the functional test pattern is judged at step 52. At step 54, the results from the functional test pattern are stored, and then a reset is performed so that additional functional test pattern may be performed if desired. At step 56, a determination is made as to whether another functional test pattern will be performed, or whether the last functional test pattern has been performed.

Meanwhile, as the functional test pattern results are judged and stored in the main program at steps 52 and 54, the pattern generator 18 continues operating chip 14, thereby keeping it active, by running an infinite loop at step 44. After a the functional test pattern ends at step 42, and FLAG2 has not yet been set, the pattern generator 18 continues an infinite loop at step 44 that keeps chip 14 active.

If it is determined at step 56, however, that another functional test pattern will be performed, then the main program sets FLAG2 at step 58. Once FLAG2 is set, the pattern generator 18 gets out of the infinite loop at step 44, and then proceeds to reset FLAG1 at step 46. Next, pattern generator 18 jumps to the next functional test pattern at step 48, and loops back to run the next functional test pattern at step 40.

This process of sequencing through functional test patterns may be repeated such that pattern generator 18 may generate any number of multiple functional test patterns. Unlike prior systems, however, pattern generator 18 keeps semiconductor chip 14 active and running between functional test patterns. Even while the main program retrieves the test results for the various functional test patterns, semiconductor chip 14 continues to run. In this way, semiconductor chip 14 never goes to a static or undefined state between the individual functional test patterns.

When the last functional test pattern is encountered at step 56, main program will stop running functional tests at step 60. The results of the last functional test pattern are then judged at step 62 and stored at step 64. All of the results from the plurality of functional test patterns may then be processed and judged at step 66 before ending the functional tests at step 70.

In one embodiment illustrating by the flow diagram, semiconductor chip 14 is kept active and running between the various functional test patterns by continuing to provide a clock signal and input signals to the semiconductor chip 14, even when functional test patterns are not being run. By continuing to supply the clock and input signals to the semiconductor chip 14, this ensures that the semiconductor chip 14 never goes to a static or undefined state between the individual functional test patterns. This may be useful in situations where the states set within semiconductor chip 14 by the running of a first functional test pattern are used or relied upon is running a second functional test pattern after the first. If these states within the semiconductor chip 14 were allowed to go to a static or undefined state between the individual functional test patterns, the second functional test pattern may well produce results that are not reliable.

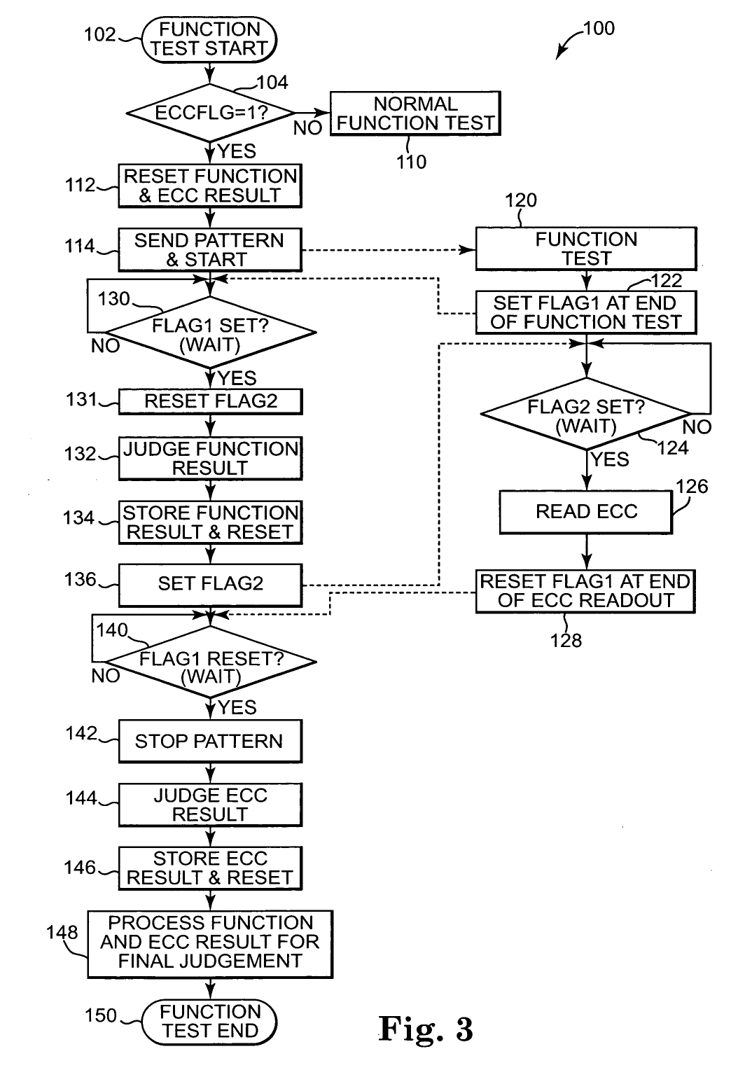

FIG. 3 is flow diagram illustrating an alternative embodiment of test system 10 according to an embodiment of the present invention. In one embodiment, steps 102 through 114 and steps 130 through 150 represent functions of the main program that is running in the main processor 16, and in that same embodiment, steps 120 though 128 represent functional test patterns that are running in the pattern generator 18.

At step 102, functional test patterns start in the main program. At step 104, a determination is made as to whether an error correction code (“ECC”) will be run following a functional test pattern. If an ECC is not to be run, then an ECC flag is not set, such that ECCFLG does not equal 1, and the main program executes a normal function test at step 110. This normal function test at 110 may be similar to that described above with reference to FIG. 2.

If an ECC is to be run, however, then the ECC flag is set, such that ECCFLG equals 1, and the main program proceeds to reset the function and ECC results from any previous tests at step 112, thereby eliminating any pass/fail decision from previous patterns. Next at step 114, a functional test pattern is sent to the pattern generator 18. In this way, the pattern generator 18 at step 120 initiates a first functional test pattern. Thus, the pattern generator 18 powers up the semiconductor chip 14 under test, and it writes data to chip 14 and reads data from chip 14. Once the functional test pattern is finished, an internal flag (FLAG1) in the pattern generator 18 is set at step 122 at the end of this functional test pattern. Pattern generator 18 then enters an infinite loop at step 124 until FLAG2 is set.

At the same time that the functional test pattern is initiated by the pattern generator 18 at step 120, the main program in the main processor 16 enters an infinite loop at step 130. When the functional test pattern is initiated by the pattern generator 18 at step 120, FLAG1 has not yet been set such that the main program in the main processor 16 continues to loop at step 130. This infinite loop continues until FLAG1 is set at the end of the functional test pattern at step 122. After the functional test pattern ends and returns a result at step 122, FLAG2 is reset at step 131 and then the result from the functional test pattern is judged at step 132. At step 134, the results from the functional test pattern are stored, and then a reset is performed so that additional functional test pattern may be performed if desired. At step 136, FLAG2 is set and the main processor 16 again enters an infinite loop at step 140, and will remain there until FLAG1 is reset.

In the meantime, once FLAG2 is set at step 136, pattern generator 18 then is removed from the infinite loop at step 124, because FLAG2 is now set. Thus, ECC will be read at step 126. Then, FLAG1 is reset at step 128 at the end of ECC readout. This will remove the main program from the infinite loop at step 140, allowing it to move to step 142 and stop the functional test pattern. The results of the functional test pattern and ECC are then judged at step 144 and stored at step 146. All of the results from the plurality of functional test patterns and ECC tests may then be processed and judged at step 148 before ending the functional tests at step 150.

With the above-described embodiment, as the functional test pattern results are judged and stored in the main program at steps 132 and 134, the pattern generator 18 continues operating semiconductor chip 14, thereby keeping it active, by running an infinite loop at step 124. Thus, when the ECC status is read at step 126, semiconductor chip 14 is still active from the functional test pattern. In this way, important information within semiconductor chip 14 is not lost in the time period between the functional test pattern and reading the ECC status.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A testing system for testing a manufactured semiconductor component, the testing system comprising:
a main processor configured to run a main program; and
a pattern generator configured to generate a plurality of functional test patterns, each test pattern assembled to test the manufactured semiconductor component thereby producing a test result for each test pattern;
wherein the main processor and main program communicate with the pattern generator and functional test patterns such that the plurality of functional test patterns are sequentially run on the manufactured semiconductor component, such that the main program receives the test result of each functional test pattern after it is run, and such that the manufactured semiconductor component continues to operate between each of the functional test patterns.

2. The testing system of claim 1, wherein the main program communicates with the each of the functional test patterns such that the functional test patterns inform the main program when a functional test is complete so that the main program can store the test result while the pattern generator continues to operate the manufactured semiconductor component.

3. The testing system of claim 2, further comprising a clock signal delivered to the manufactured semiconductor component during testing, and wherein the main processor and main program communicate with the pattern generator and functional test patterns such that the clock signal continues operating in the manufactured semiconductor between the functional test patterns while the main program stores the test results.

4. The testing system of claim 3, wherein the test results are an indication of whether the manufactured semiconductor component passed or failed the functional test pattern applied by the pattern generator.

5. The testing system of claim 4, wherein the main program stores an indication of whether the manufactured semiconductor component passed or failed the functional test pattern applied by the pattern generator.

6. A method of testing a manufactured semiconductor component, the method comprising:
running a main program on a main processor;
generating a first functional test pattern on a pattern generator such that the first functional test pattern tests the manufactured semiconductor component thereby producing a first test result;
interfacing the main program with the pattern generator such that the main program retrieves the first test result;
generating a second functional test pattern on the pattern generator such that the second test pattern tests the manufactured semiconductor component thereby producing a second test result; and
operating the manufactured semiconductor component continuously between the first and second functional test patterns such that the manufactured semiconductor component stays active between the first and second functional test patterns.

7. The method of claim 6, further comprising interfacing the main program with the first and the second functional test patterns such that the functional test patterns inform the main program when a functional test pattern is complete so that the main program can store the test result while the pattern generator continues to operate the manufactured semiconductor component.

8. The method of claim 7, further comprising delivering a clock signal to the manufactured semiconductor component during testing, and interfacing the main processor and main program with the pattern generator and functional test patterns such that the clock signal continues operating in the manufactured semiconductor between the functional test patterns while the main program stores the test results.

9. The testing system of claim 8, further comprising storing an indication of whether the manufactured semiconductor component passed or failed the functional test pattern applied by the pattern generator.

10. An apparatus comprising:
a manufactured semiconductor component; and
a pattern generator coupled to the manufactured semiconductor component and configured to generate a first functional test pattern that runs in the manufactured semiconductor component thereby producing a first test result;
the pattern generator further configured to generate an error correction code pattern that runs in the manufactured semiconductor component to detect an error correction code status of the manufactured semiconductor component;
wherein the pattern generator continues to operate the manufactured semiconductor component between running the first functional test pattern and running the an error correction code pattern such that the manufactured semiconductor component stays active.

11. The apparatus of claim 10, further comprising a main processor configured to run a main program, wherein the main processor and main program communicate with the pattern generator to control the running of the first functional test pattern and of the error correction code pattern.

12. The apparatus of claim 11, wherein the main processor and main program control the pattern generator such that the first functional test pattern runs on the manufactured semiconductor component, then the first test result is retrieved by the main program, then the error correction code pattern runs in the manufactured semiconductor component, then the main program detects the error correction code status of the manufactured semiconductor component, and such that the manufactured semiconductor component continues to operate throughout.

13. The apparatus of claim 10, further comprising a clock signal delivered to the manufactured semiconductor component during testing, and wherein the main processor and main program communicate with the pattern generator and functional test patterns such that the clock signal continues operating in the manufactured semiconductor between the running of the first functional test pattern and the error correction code pattern.

14. A testing system for testing a manufactured semiconductor component, the testing system comprising:
means for generating a plurality of functional test patterns, each test pattern assembled to test the manufactured semiconductor component thereby producing a test result for each test pattern; and
means for sequentially running the plurality of functional test patterns on the manufactured semiconductor component while continuing to operate the manufactured semiconductor component between the running of each of the functional test patterns.

15. The testing system of claim 14, further comprising a main processor configured to run a main program, wherein the main processor and main program communicate with the means for generating a plurality of functional test patterns to control the running of the functional test patterns.

16. The apparatus of claim 15, further comprising means for generating an error correction code pattern that runs in the manufactured semiconductor component to detect an error correction code status of the manufactured semiconductor component.

17. The apparatus of claim 16, wherein the manufactured semiconductor component continues operating between running of the functional test patterns of the error correction code pattern.

18. The apparatus of claim 14, further comprising a clock signal delivered to the manufactured semiconductor component during testing such that the clock signal continues operating in the manufactured semiconductor component between the running of the functional test patterns.

19. A method for testing a manufactured semiconductor component, the method comprising:
generating a plurality of functional test patterns, each test pattern assembled to test the manufactured semiconductor component thereby producing a test result for each test pattern; and
sequentially running the plurality of functional test patterns on the manufactured semiconductor component while continuing to operate the manufactured semiconductor component between the running of each of the functional test patterns.

20. The method of claim 19, further comprising generating an error correction code pattern that runs in the manufactured semiconductor component to detect an error correction code status of the manufactured semiconductor component.

21. The apparatus of claim 20, wherein the manufactured semiconductor component continues operating between running of the functional test patterns of the error correction code pattern.

22. A testing system comprising:
a main processor configured to run a main program; and
a pattern generator configured to generate a plurality of functional test patterns; and
a manufactured random access memory device coupled to the pattern generator;
wherein the main processor and main program communicate with the pattern generator and plurality of functional test patterns such that the plurality of functional test patterns run sequentially on the manufactured random access memory device; and
wherein the manufactured random access memory device continues to operate between each of the plurality of functional test patterns.

23. The testing system of claim 22, wherein the pattern generator is further configured to generate an error correction code pattern that runs in the manufactured random access memory device in order to detect an error correction code status of the manufactured random access memory device.

24. A method for testing a manufactured random access memory device, the method comprising:
running a main program on a main processor configured;
generate a plurality of functional test patterns on a pattern generator;
running the plurality of functional test patterns, under the control of the main program, such that the plurality of functional test patterns run sequentially on the manufactured random access memory device; and
continuously operating the manufactured random access memory device between each of the plurality of functional test patterns.
